(19) United States
(12) Patent Application Publication
(10) Pub. No.: US 2011/0186338 A1
(43) Pub. Date: Aug. 4, 2011

(54) POLYMERIC POSITIVE TEMPERATURE COEFFICIENT LIQUID COMPOSITION

(76) Inventor: Micha Leitner, Prestwich (GB)

(21) Appl. No.: 12/996,094

(22) PCT Filed: May 28, 2009
(86) PCT No.: PCT/GB2009/050577

§ 371 Date: Mar. 7, 2011

(30) Foreign Application Priority Data
Jun. 3, 2008 (GB) 0810031.5

(51) Int. Cl. H05K 1/09; H01B 1/12; H05K 3/12; H05K 3/14

(52) U.S. Cl. 174/257; 252/500; 427/98.4

(57) ABSTRACT

Liquid compositions contain electrically conductive particles and are printable. Following printing onto substrates, liquid compositions can be solidified to produce polymeric positive temperature coefficient materials. Polymeric thermoplastic positive temperature coefficient materials produced from such compositions. Processes include printing liquid compositions containing electrically conductive particles; and solidifying the liquid compositions to form polymeric positive temperature coefficient materials.

### TECHNICAL FIELD

The invention relates to polymeric positive temperature coefficient materials.

### BACKGROUND

Positive temperature coefficient materials, or PTC materials for short, are materials whose electrical resistance reversibly increases with their temperature. Typically this exhibits itself as a low inherent resistance combined with a sudden increase in resistance with increasing temperature in a specific temperature range, called the switching temperature.

This ability to vary its resistance significantly without any moving parts has resulted in the use of PTC materials in thermostatically controlled heaters and circuit protection components.

PTC materials have the potential to bring a whole range of further benefits as electronic circuit protection components in view of their unique properties. For example, the ability to behave as a resettable fuse to provide electronic surge protection, e.g. when electronic equipment is switched on has significant potential.

US 2006/0049385 discloses a PTC material comprising a polyethylene matrix interspersed with carbon black particles.

Such an arrangement provides an inherent conductivity due to the connections provided by adjacent particles. Upon heating the polyethylene matrix expands, causing the particles to separate and thus breaking the connection, and the electrical resistance increasing.

Polyethylene undergoes significant thermal expansion at around 125° C., providing the desired rapid increase in resistance and a short temperature range.

However, polyethylene has practical difficulties particularly in applications involving electrical circuit protection. For example polyethylene does not lend itself well to application by printing which is a convenient method of applying materials directly where they are needed.

Furthermore, as polyethylene expands it also softens becoming mechanically unstable, which can result in a lack of repeatability. Additionally, the simple molecular structure of polyethylene limits the range of PTC properties that can be achieved. In particular it is difficult to arrange for its glass transition temperature to be much higher or lower than 125° C.

### SUMMARY OF THE INVENTION

In a first aspect, the invention relates to a liquid composition comprising electrically conductive particles which is printable and, following printing onto a substrate, is solidifiable to produce a polymeric thermoplastic positive temperature coefficient material.

In a second aspect, the invention relates to a polymeric thermoplastic positive temperature coefficient material comprising conductive particles, which is obtainable by the process of printing a liquid composition followed by its solidification.

In a third aspect, the invention relates to a process of printing a liquid composition comprising electrically conductive particles, followed by solidifying the composition thereby to produce a polymeric thermoplastic positive temperature coefficient material.

The PTC materials produced by the present invention are more conveniently incorporated into electronic circuits because they are printable. Additionally as the invention is not reliant on polyethylene, a wider range of material properties are possible.

The PTC material thus formed preferably has a resistivity at 25° C. of less than 10 ohm cm, preferably less than 1 ohm cm, more preferably less than 0.1 ohm cm.

Additionally, the PTC material thus formed preferably increases its resistivity one thousand fold as its temperature is increased from 25° C. to 125° C., preferably it increases ten thousand fold, more preferably one hundred thousand fold.

Any appropriate printing method may be employed, however preferred printing methods include screen printing and inkjet printing. Screen printing is most preferred.

Preferred solidifying methods include polymerisation and solvent evaporation. Polymerisation is preferred.

A wide range of conducting particles may be included, however carbon black particles and metal particles are preferred. Particles having a mean particle size in the range of from 20 to 160 nm have provided good results.

It has been found that a conductive particle concentration of from 10 to 60 weight % based on the liquid, gives good results.

When the solidification method is polymerisation, the liquid composition comprises polymerisable materials such as monomers and/or oligomers, preferably at levels of from 40 to 90 weight % of the liquid.

Preferably the polymerisable materials comprise an acrylate. Suitable acrylates include polyester acrylate, a diacrylate, a triacrylate and mixtures thereof. Methyl methacrylate is a preferred acrylate. Mixtures of diacrylate and triacrylate are particularly preferred.

A preferred polyester acrylate has the formula

CH₂═CHCO₂[R—O₂CR¹CO₂R]ₙO₂CCH═CH₂

R is preferably an aromatic, aliphatic or cycloaliphatic alcohol, preferably methyl alcohol. R¹ is preferably an aromatic, aliphatic or cycloaliphatic carboxylic acid, preferably methacrylic acid. Preferably n is from 10 to 3000. One such preferred polyester acrylate is UVP6000 from Polymer Technologies Limited.

A preferred diacrylate is hydroxy diethyl diacrylate, a material having the formula

CH₂═CH—C(O)—O—[CH₂]ₙ—O—C(O)—CH═CH₂,

wherein n is preferably from 1 to 10, and mixtures thereof. Preferably n is 6. One such preferred diacrylate is Etermer 221 from Polymer Technologies Limited.

Polymerisation may be initiated by any convenient method, however ultra violet (UV) initiation is preferred. Therefore, the liquid composition preferably comprises a UV initiator. Such a UV initiator will desirably be present at a level of from 1.0 to 5.0 weight % of the liquid composition. A preferred initiator is one or more Irgacure UV initiators from Ciba Speciality Chemicals.

The substrate onto which the liquid composition is deposited may take a variety of forms. Preferably the substrate is electronically insulating. Preferably the liquid and resulting PTC material is in contact with at least two electrically conducting electrodes.

In a particularly preferred embodiment the insulating substrate is a printed circuit board, preferably the material is also in contact with at least two electrically conductive electrodes, e.g. the tracks or pads of the circuit board. Thus, the PTC device can be made as part of the printed circuit board, allowing it to be specified as desired, in precisely shaped areas.

For example, an insulating material may be deposited between two copper tracks on a printed circuit board. This is then followed by printing the PTC material to bridge the two copper tracks and on top of the insulating material.

In an alternative preferred embodiment the PTC material in contact with the at least two electrodes, forms a PTC device, for example a surface mount component.

The PTC material may desirably be coated with a protective coating. Until now, PTC materials have been used to trigger when there is excess current, however, the present invention allows embodiments wherein the PTC material protects against excess heating.

In one convenient embodiment, PTC material is printed to connect two conductive power rails and positioned beneath the device to be protected. Power to the device is passed through the PTC material. Once the device overheats, the PTC material increases its resistance significantly, thus reducing the current flow to the device until it has cooled sufficiently.

In a preferred embodiment, the thickness of the PTC material in contact with the device is greater than that not in contact with the device. Typically the change in thickness will be gradual. Once the device heats up, the PTC material in contact with it also heats up thus it increases its resistance and starts to dissipate heat of its own. Initially the PTC material not in contact with the device remains cool, but as there is less PTC material due to its lower thickness, the current is more concentrated and a band of hot PTC material begins to move away from the device. This causes heat to be generated in the PTC material itself, rather than in the device, and also moves the area in which heat is generated away from the device. The combined effect cools down the device while the PTC material remains hot and protects the device from current flow.

The invention will now be illustrated, by way of example, and with reference to the following figures in which:

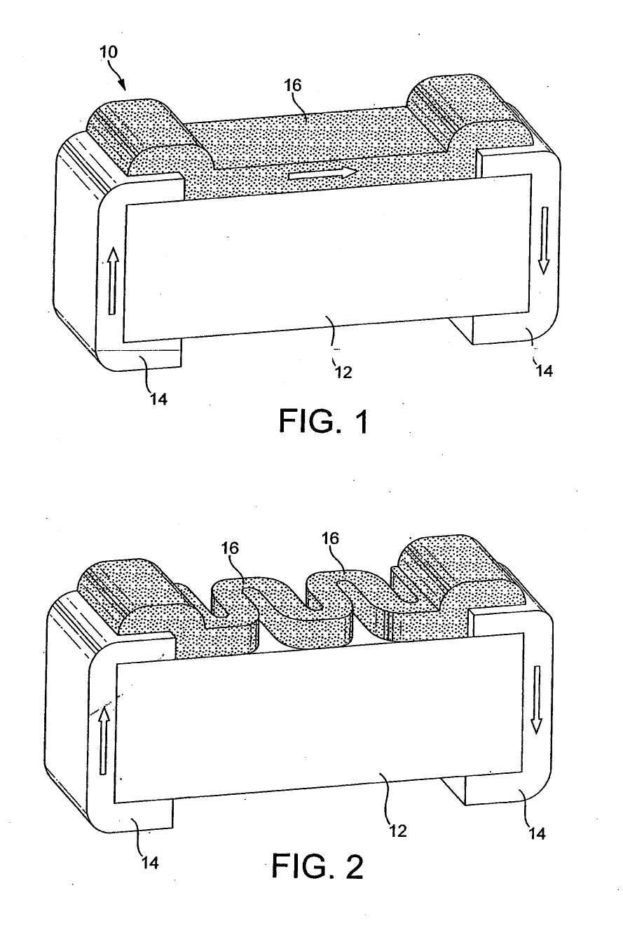

FIG. 1 is an illustration of a surface mount component comprising PTC material according to the present invention.

FIG. 2 is an illustration of another surface mount component comprising a PTC material according to the present invention.

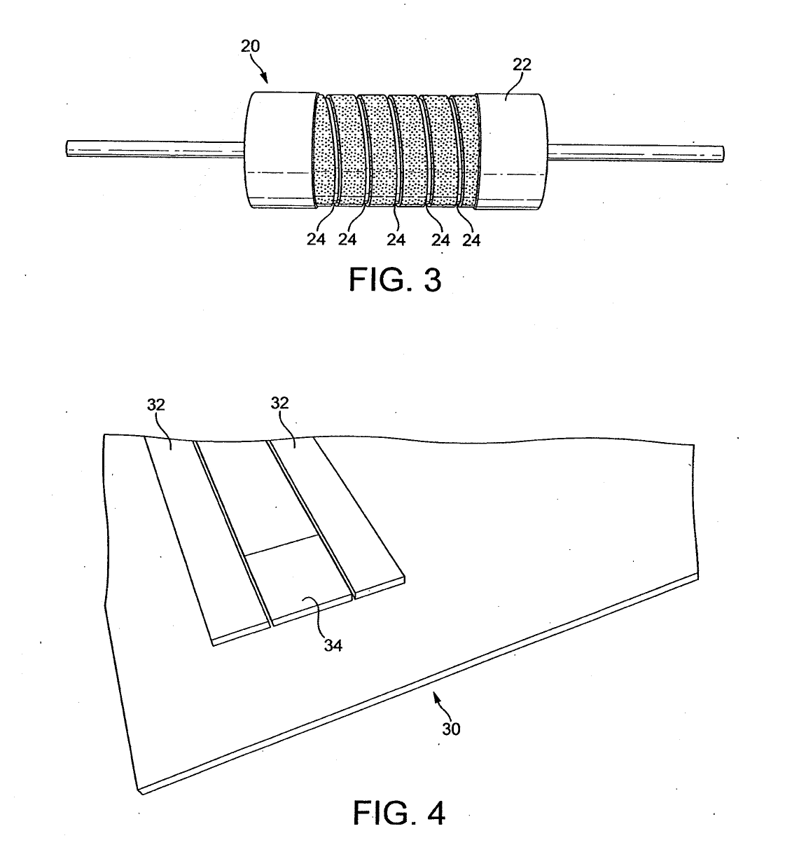

FIG. 3 is an illustration of another electronic component comprising PTC material according to the present invention.

FIG. 4 is an illustration of part of a printed circuit board onto which PTC material is to be printed.

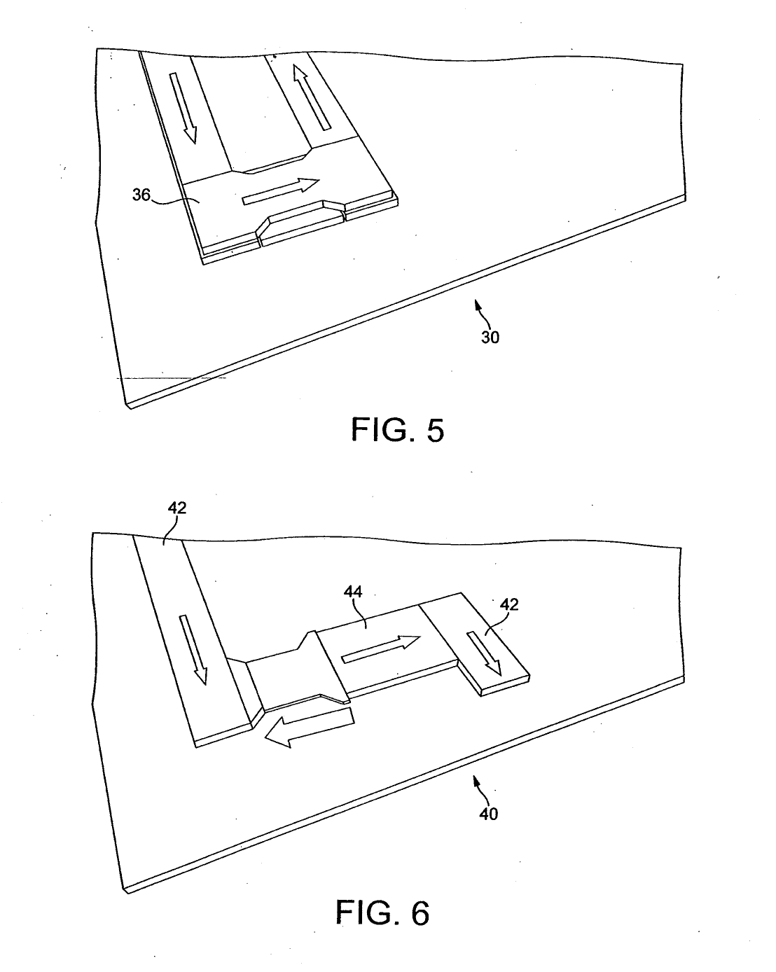

FIG. 5 is an illustration of the printed circuit board shown in FIG. 4, wherein PTC material has been deposited.

FIG. 6 is an illustration of a printed circuit board wherein PTC material according to the present invention is used to protect a device from excess heating.

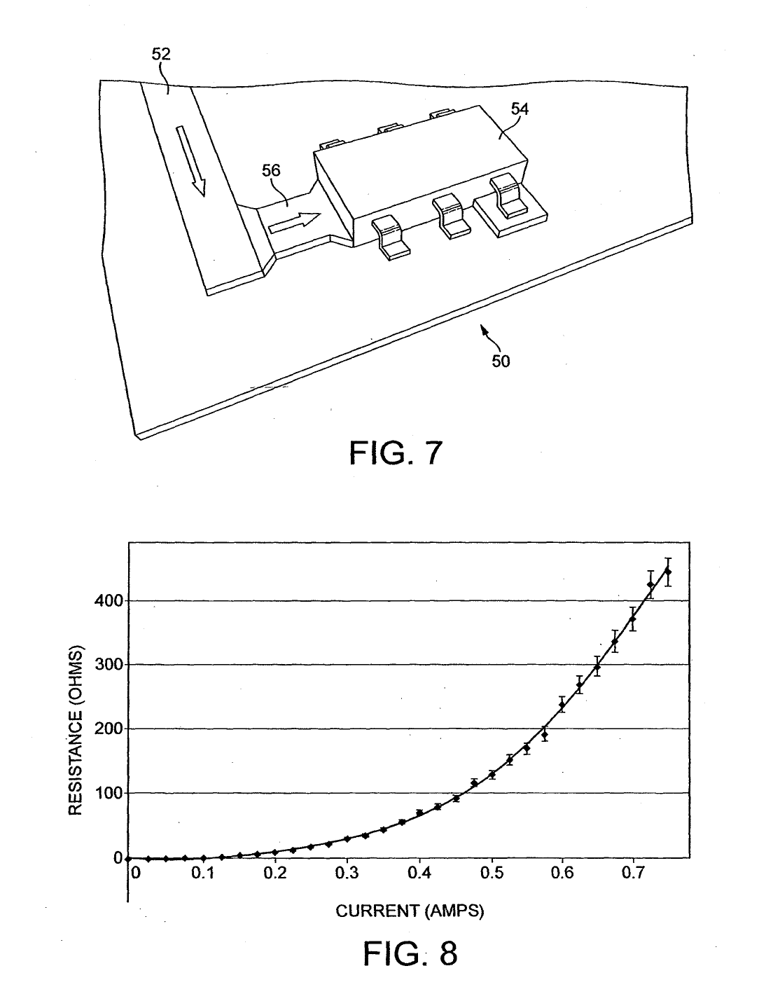

FIG. 7 is an illustration of a printed circuit board comprising an integrated circuit connected to a power rail via printed PTC material according to the present invention.

FIG. 8 is a chart showing electrical resistance (ohms) versus electrical current (amps).

Turning to the figures, FIG. 1 shows a surface mount component 10 comprising insulating substrate 12 and conductive copper end caps 14. PTC material 16 has been printed along the top so as to bridge the end caps 14.

The ability to print the PTC material on the top of the device makes it easier to produce such devices of different electrical characteristics, thus enabling a range of devices to be produced on the same production run.

FIG. 2 shows a surface mount component similar to that shown in FIG. 1, wherein the PTC material has been deposited in a pattern to provide a greater length. Such a device could be more useful for lower voltage circuits where the currents are smaller and a more sensitive protection component is needed. It can be seen that printing the PTC material 16 can result in any pattern desired.

FIG. 3 shows a low power protection component incorporating a PTC material 22 formed in a similar manner to that in which conventional resistors are manufactured. Into the cylindrical body of the PTC material 22 has been carved a helical groove 24. The advantage of forming the PTC material in such a long compact spiral is that it enables the surface area of the device to be reduced, and therefore reduce the amount of power or heat that needs to be dissipated by the circuit in order to keep the device in a tripped state.

FIG. 4 shows part of a printed circuit board 30 comprising conductive copper tracks 32 with an insulating pad 34 between them. The insulating pad 34 is chosen to be capable of withstanding the higher temperatures attained when the PTC material is in its high resistance state.

FIG. 5 shows the section of printed circuit board 30 shown in FIG. 4. PTC material 36 has been deposited over the top of the tracks 32 and insulating pad 34. In the event that the current flow begins to increase, the heat dissipated by the PTC material will cause its resistances to increase dramatically, thus preventing the flow of current. As may be seen from FIG. 5, the thickness of the PTC material increases as it moves away from the current carrying component. This arrangement is believed to be advantageous, in directing heat away from the electrical components.

FIG. 6 shows another section of printed circuit board 40 comprising conductive power rails 42 with a PTC material 44 connected between them. The device to be protected (not shown) is positioned on top of the PTC material, and derives power from conductive rails 42. Once the device heats up, the PTC material 44 will also be heated, and its resistance will increase. Once again, the varying thickness of the PTC material ensures that heat is transmitted away from the device.

FIG. 7 shows another section of printed circuit board 50 comprising conductive copper rail 52 and integrated circuit 54 between the integrated circuit 54 and the copper rail 52 is PTC material 56. If the integrated circuit starts to generate excessive heat, this will be transmitted to the PTC material in contact with it. If the temperature of the PTC material 56 becomes high enough, its resistance will increase and it will start to dissipate heat in its own right. Some of this heat will be conducted from the PTC material immediately away from the device. However as can be seen from FIG. 7, the PTC material is shaped so that it is less thick away from the device, so that current is concentrated away from the device. This has the effect that there will be more heat generated away from the device than closer to it. Thus, a band of hot, high resistance PCT material will therefore move away from the device. This should have two beneficial effects: firstly the increased resistance of the PTC material will cause heat to be generated in the PTC material rather than in the integrated circuit itself. Secondly, the area in which heat is generated will move away from the device. The combined effect should be to allow this device to cool down, while the PTC material remains at a high temperature and thereby protects the electronic device itself from harm.

### EXAMPLES

Liquid compositions having the following formulas were manufactured by blending the ingredients together in a Banbury mixer.

| Material | 1 | 2 |
|---|---|---|
| Polyester Acrylic | — | 20.7 |
| Diacrylate | 54.5 | 41.4 |
| Triacrylate | 27.4 | 20.6 |
| UV Initiator | 4.5 | 3.5 |
| Carbon Black particles | 13.6 | 13.8 |
| Total | 100 | 100 |

The materials were screen printed onto a region of insulating substrate such that it contacts two copper foil electrodes. The liquid was then exposed to UV light and allowed time to cure. The resulting material had PTC properties. Where the polyester acrylic is UVP600 from Polymer Technologies Ltd, the diacrylate is EM 221 from Polymer Technologies Ltd, the triacrylate is EM 231 from Polymer Technologies Ltd, the UV initiator is Irgacure from Ciba Speciality Chemicals, and the carbon black is grade 3030B from Mitsubishi Corporation.

A liquid composition having the following formula was manufactured by blending the ingredients together in a Banbury mixer.

| Material | 3 | 4 |
|---|---|---|
| Acrylic resin | 50.0 | 32.5 |
| Toluene | — | 48.0 |
| Xylene | 31.9 | — |
| PM acetate | 10.4 | 13.0 |
| Carbon black | 7.7 | 6.5 |

As before, the liquid was printed onto a region of insulating substrate such that it contacts two copper foil electrodes. The liquid was then air dried until it solidified. The resulting solid material had PTC properties.

The acrylic resin is Paraloid B-99 from Rohm and Haas.

Example 4 was deposited onto an insulating substrate so as to bridge two aluminum foil electrodes. The electrodes were each 5.0 cm in length, and separated from each other by 50 micrometres. Electrical current was passed through the electrodes and through the material of example 4 and the electrical resistance of the material measured. The results are shown in FIG. 8.

As can be seen from FIG. 8, the material is highly conductive at low current and therefore low temperature. At higher currents a steep rise in electrical resistance occurs.

1. A liquid composition comprising electrically conductive particles wherein the liquid composition is printable and, following printing onto a substrate, is solidifiable to produce a polymeric thermoplastic positive temperature coefficient material.

2. A polymeric thermoplastic positive temperature coefficient material comprising conductive particles, wherein the polymeric thermoplastic positive temperature coefficient material is obtained by a process of printing a liquid composition followed by its solidification.

3. A process comprising:
printing a liquid composition comprising electrically conductive particles; and
solidifying the composition thereby to produce a polymeric thermoplastic positive temperature coefficient material.

4. The composition according to claim 1, wherein the printing is screen printing or inkjet printing.

5. The composition according to claim 1, wherein the conductive particles are present at a concentration from 10 to 60 weight % based on the liquid composition.

6. The composition according to claim 1, wherein the solidification occurs by polymerization or solvent evaporation.

7. The composition according to claim 6, wherein the solidification occurs by polymerization.

8. The composition according to claim 7, wherein the liquid composition comprises a polymerisable material at a level of from 40 to 90 weight % of the liquid composition.

9. The composition according to claim 7, wherein the polymerisable material comprises an acrylate.

10. The composition according to claim 7, wherein the liquid composition comprises a UV initiator.

11. The composition according to claim 1, wherein the substrate is electronically insulating.

12. The composition according to claim 1, wherein the liquid composition and the polymeric thermoplastic positive temperature coefficient material are in contact with at least two electrically conducting electrodes.

13. The composition according to claim 1, wherein the substrate is a printed circuit board.

14. The composition according to claim 1, wherein the polymeric thermoplastic positive temperature coefficient material is shaped to have a reduced thickness in a direction away from a component to be protected.

15. The material according to claim 2, wherein the printing is screen printing or inkjet printing.

16. The process according to claim 3, wherein the printing is screen printing or inkjet printing.

17. The material according to claim 2, wherein the conductive particles are present at a concentration from 10 to 60 weight % based on the liquid composition.

18. The process according to claim 3, wherein the conductive particles are present at a concentration from 10 to 60 weight % based on the liquid composition.

19. The material according to claim 2, wherein the solidification occurs by polymerization or solvent evaporation.

20. The process according to claim 3, wherein the solidification occurs by polymerization or solvent evaporation.
